(19) United States
(12) Patent Application Publication
(10) Pub. No.: US 2009/0172422 A1
(43) Pub. Date: Jul. 2, 2009

(54) KEYBOARD WITH DETACHABLE RECHARGEABLE MOUSE

(76) Inventors: Robert Campesi, Cupertino, CA (US); Benjamin Abraham, Cupertino, CA (US); Yancy Chen, Campbell, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/966,593

(22) Filed: Dec. 28, 2007

(51) Int. Cl. G06F 1/26; G06F 1/16; G06F 13/20; H03K 17/94; G06F 13/12

(52) U.S. Cl. 713/300; 710/62; 710/303; 710/1; 341/22

(57) ABSTRACT

In one embodiment an electronic device comprising a keyboard coupled to a power supply and a mouse coupled to the keyboard. In one embodiment the keyboard further has a docking station into which the rechargeable mouse or other input device can be mounted. Furthermore, in one embodiment, the mouse can be used while in the keyboard or when separated from the keyboard through a wired or wireless connection.

### TECHNICAL FIELD

This application relates to electronic computing, and more particularly keyboard and mouse usage and configuration in computer systems.

### BACKGROUND

The configuration and placement of a keyboard and mouse within one's workspace has been a continuing problem. Current configurations provide for either a keyboard and mouse which are both wired to a computer, or a keyboard and mouse which are both wireless. The wired solution does not provide the flexibility needed to provide for a pleasant workspace, and the wireless solution relies on batteries with a short lifespan. Additionally, wireless rechargeable mice that are currently available require a separate docking station which takes up an additional port in the computer.

### BRIEF DESCRIPTION OF THE DRAWINGS

FIG. 1 is a schematic illustration of a computer system comprising a keyboard with a docking station for a mouse, according to embodiments.

FIG. 2 is a schematic illustration of a keyboard with docking station and mouse, according to embodiments.

FIG. 3 is a flowchart illustrating operations in one embodiment of a keyboard control module.

FIG. 4 is a schematic illustration of a computing environment, according to embodiments.

### DETAILED DESCRIPTION

Described herein are exemplary systems and methods for implementing a keyboard with docking station and mouse system with an electronic such as, e.g., a computing system. Some of the methods described herein may be embodied as logic instructions on a computer-readable medium. When executed on a processor, the logic instructions cause a general purpose computing device to be programmed as a special-purpose machine that implements the described methods. The processor, when configured by the logic instructions to execute the methods recited herein, constitutes structure for performing the described methods.

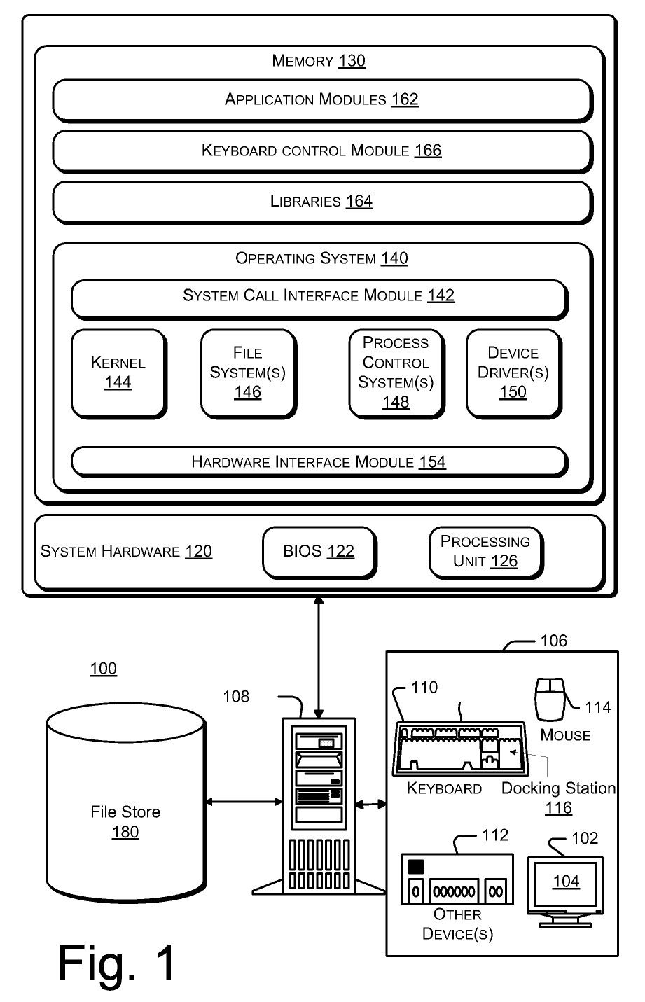

FIG. 1 is a schematic illustration of a computing system 100 adapted to include a keyboard 110 with a docking station 116 capable of docking devices, such as, a mouse 114 or various other I/O devices 112, according to some embodiments. In the illustrated embodiment, system 100 may be embodied as a hand-held or stationary device for accessing the Internet, a desktop PC, notebook computer, personal digital assistant, or any other processing devices.

The computing system 100 includes a computer 108 and one or more accompanying input/output devices 106 including a display 102 having a screen 104, a keyboard 110 with a docking station 116, and other I/O device(s) 112, and a mouse 114. The other device(s) 112 can include a touch screen, a voice-activated input device, a track ball, and any other device that allows the system 100 to receive input from a developer and/or a user. Additionally, the mouse 114 and other I/O devices 112 may dock with the keyboard 110 for purposes, such as but not limited to, recharging or providing additional functionality to the keyboard 110. The computer 108 includes system hardware 120 including at least processing unit 126, a basic input/output system (BIOS) 122, and random access memory and/or read-only memory 130. A file store 180 is communicatively connected to computer 108. File store 180 may be internal such as, e.g., one or more hard drives, or external such as, e.g., one or more external hard drives, network attached storage, or a separate storage network.

Memory 130 includes an operating system 140 for managing operations of computer 108. In one embodiment, operating system 140 includes a hardware interface module 154 that provides an interface to system hardware 120. In addition, operating system 140 includes a kernel 144, one or more file systems 146 that manage files used in the operation of computer 108 and a process control subsystem 148 that manages processes executing on computer 108. Operating system 140 further includes one or more device drivers 150 and a system call interface module 142 that provides an interface between the operating system 140 and one or more application modules 168 and/or libraries 164. The various device drivers 150 interface with and generally control the hardware installed in the computing system 100.

In operation, one or more application modules 162 and/or libraries 164 executing on computer 108 make calls to the system call interface module 142 to execute one or more commands on the computer's processor. The system call interface module 142 invokes the services of the file systems 146 to manage the files required by the command(s) and the process control subsystem 148 to manage the process required by the command(s). The file system(s) 146 and the process control subsystem 148, in turn, invoke the services of the hardware interface module 154 to interface with the system hardware 120. The operating system kernel 144 can be generally considered as one or more software modules that are responsible for performing many operating system functions.

The particular embodiment of operating system 140 is not critical to the subject matter described herein. Operating system 140 may be embodied as a UNIX operating system or any derivative thereof (e.g., Linux, Solaris, etc.) or as a Windows® brand operating system.

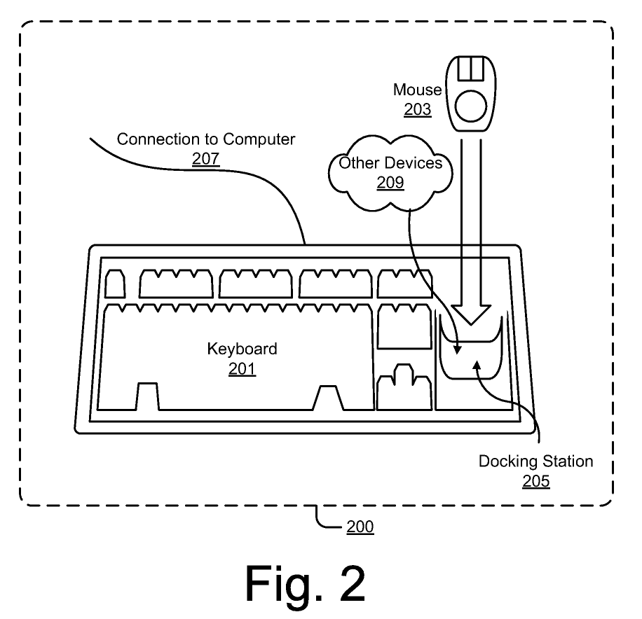

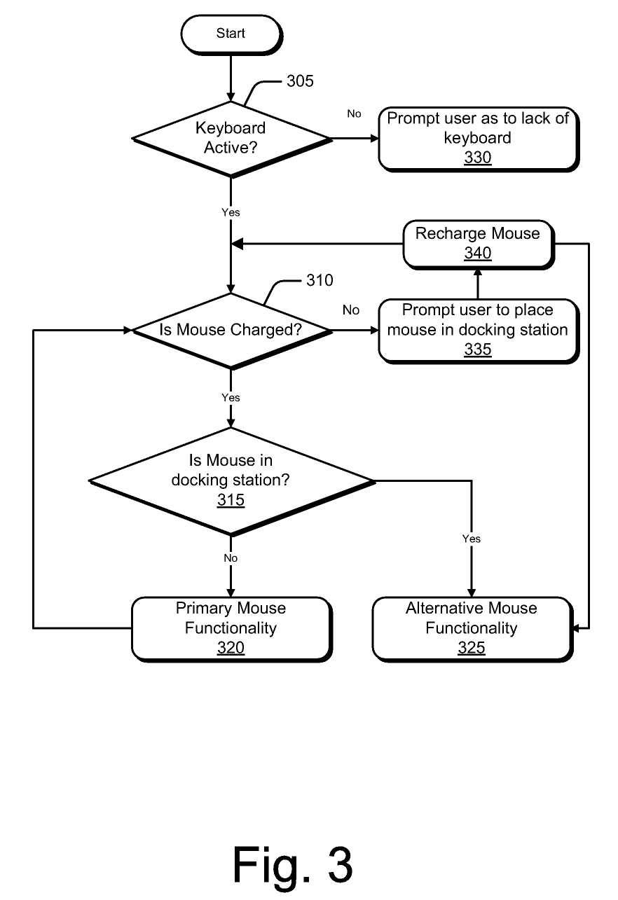

In some embodiments, computer system 100 comprises a keyboard control module 166, which may be embodied as logic instructions recorded in a computer readable medium. Additional details about the keyboard 110 with docking station 116 and the keyboard control module 166 are discussed below with reference to FIG. 2, and FIG. 3.

FIG. 2 is a schematic illustration of the keyboard system 200, according to embodiments. The keyboard system 200 comprises components, such as, a keyboard 201, a mouse 203, a docking station 205, and other devices 209 capable of docking with the keyboard. In the context of this invention, “docking” describes, but is not limited to, the action of connecting a device to another device for purposes such as, but not limited to, charging and communicating. In some embodiments, the keyboard system 200 may have additional data communication methods, such as but not limited to, a USB hub.

The keyboard system 200 is communicatively connected to the computer system 100 through an interface, such as but not limited to, a universal serial bus (USB) cable 207. In one embodiment, the connection 207 with the computer system provides for both a power supply and data transfer between the computer system and the keyboard system 200.

In some embodiments, the mouse 203 is communicatively connected to the keyboard 201. By way of example, and not limitation, communication methods between the keyboard 201 and mouse 203 includes wired media such as a wired network, fiber optic networks, or direct-wired connection and wireless media such as acoustic, RF, infrared and other wireless media. Combinations of any of the above should also be included within the scope of communication between the keyboard 201 and mouse 203. As used in this description, a “mouse” may describe input options such as, but not limited to; a trackball, a touch pad, a touch screen, a joystick, a remote control unit, or the like. In some embodiments, the mouse maintains functionality, or may have additional or alternative functionality, when placed in the docking station 205.

In some embodiments, the docking station 205 is communicatively connected to the keyboard. By way of example, and not limitation, communication between the keyboard and docking station may include a signal from to the docking station 205 to the keyboard 201 to determine if a device is docked and in need of recharging, or a signal from to the docking station 205 to the keyboard 201 to determine if a device is docked and may provide additional functionality to the keyboard 201. The docking station 205 may be coupled with a mouse 203 or variety of other devices 209, such as but not limited to; a trackball, a touchpad, a joystick, a graphics tablet, a game pad, a driving simulator device, a flight simulator device, a remote control unit, or the like. In one embodiment, other devices 209 may retain their functionality while in the docking station or may have additional or alternative functionality, when placed in the docking station 205.

In some embodiments, the keyboard system 200 may be implemented as a computer system such as the computer system 100 depicted in FIG. 1. In such embodiments, the device may include logic to recognize a keyboard system and to coordinate operations of the computer system and the keyboard system. For example, referring briefly to the embodiment depicted in FIG. 1, the basic input/output system (BIOS) 122 may include logic to detect the presence of a keyboard system 200 in the computer system, and to activate a keyboard control module 166 in response to the presence of a keyboard system 200.

FIG. 3 is a flowchart illustrating operations in one embodiment of a keyboard system module, such as the keyboard control module 166 depicted in FIG. 1. Referring to FIG. 3, if, at operation 305, the keyboard system is not active, then control passes to operation 330 and the computer system, such as depicted in FIG. 1, is prompted to display to the user the lack of a keyboard in the computer system. By contrast, if, at operation 305 the keyboard system is active then at operation 310 the keyboard module detects whether a mouse or other device, as depicted in FIG. 2, is charged above a threshold level. For example, the keyboard control module 166 may receive a signal indicative of a charge level from a mouse 203 or other device 209. If, at operation 310, the charge is less than or equal to a threshold charge, then the keyboard control module relays to a computer system, such as depicted in FIG. 1, a signal to prompt the user to place the mouse or other device is the docking station. In some embodiments, once the mouse or other device has been placed in the docking station, the keyboard control module prompts the mouse to be recharged and may prompt an alternative mouse use mode to be implemented. The keyboard control module continues to monitor the charge of the mouse or other device (operation 340).

By contrast, if at operation 310 the charge is above a threshold charge, then the keyboard control module detects whether the mouse or other device is in the docking station (operation 315). If, at operation 315, the mouse or other device is not in the docking station, then the keyboard control module prompts the computer system, such as depicted in FIG. 1, to receive the mouse or other device input in a primary specified mode of functionality (operation 320). When the mouse is not in the docking station, the keyboard control module continues to monitor the charge of the mouse or other device to assure the charge is above a threshold level. By contrast, if, at operation 315, the mouse is in the docking station, then the keyboard control module prompts the computer system, such as depicted in FIG. 1, to receive the mouse or other device input in an alternative specified mode of functionality (operation 325).

In some embodiments the keyboard control module 166 may include logic that switches the computer system's operating mode in response to a change in status of the keyboard system. For example, the keyboard control module 166 may monitor the operating status of the keyboard system 200. If the system remains active, then the computer system may continue normal operations. By contrast, if the keyboard system 200 becomes inactive, for example if the system is removed or otherwise inactivated, then the keyboard control module 166 may cause the computer system to enter a sleep mode. For example, the keyboard control module 166 may generate an interrupt, which may be passed to the BIOS, which in turn may place the computer system into a sleep mode.

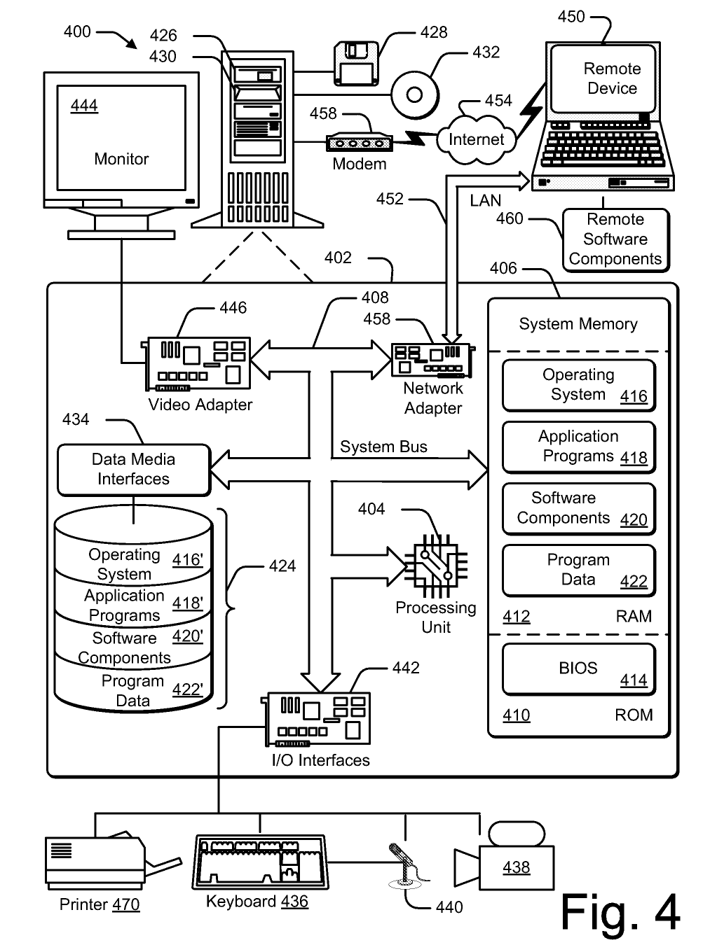

FIG. 4 is a schematic illustration of one embodiment of a computing environment. The components shown in FIG. 4 are only examples, and are not intended to suggest any limitation as to the scope of the functionality of the invention; the invention is not necessarily dependent on the features shown in FIG. 4.

Generally, various different general purpose or special purpose computing system configurations can be used. Examples of well known computing systems, environments, and/or configurations that may be suitable for use with the invention include, but are not limited to, personal computers, server computers, hand-held or laptop devices, multiprocessor systems, microprocessor-based systems, set top boxes, programmable consumer electronics, network PCs, minicomputers, mainframe computers, distributed computing environments that include any of the above systems or devices, and the like.

The functionality of the computers is embodied in many cases by computer-executable instructions, such as program modules, that are executed by the computers. Generally, program modules include routines, programs, objects, components, data structures, etc. that perform particular tasks or implement particular abstract data types. Tasks might also be performed by remote processing devices that are linked through a communications network. In a distributed computing environment, program modules may be located in both local and remote computer storage media.

The instructions and/or program modules are stored at different times in the various computer-readable media that are either part of the computer or that can be read by the computer. Programs are typically distributed, for example, on floppy disks, CD-ROMs, DVD, or some form of communication media such as a modulated signal. From there, they are installed or loaded into the secondary memory of a computer. At execution, they are loaded at least partially into the computer's primary electronic memory. The invention described herein includes these and other various types of computer-readable media when such media contain instructions, programs, and/or modules for implementing the steps described below in conjunction with a microprocessor or other data processors. The invention also includes the computer itself when programmed according to the methods and techniques described below.

For purposes of illustration, programs and other executable program components such as the operating system are illustrated herein as discrete blocks, although it is recognized that such programs and components reside at various times in different storage components of the computer, and are executed by the data processor(s) of the computer.

With reference to FIG. 4, the components of computer 400 may include, but are not limited to, a processing unit 404, a system memory 406, and a system bus 408 that couples various system components including the system memory 406 to the processing unit 404. The system bus 408 may be any of several types of bus structures including a memory bus or memory controller, a peripheral bus, and a local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus also known as the Mezzanine bus, and PCI Express (PCIE).

Computer 400 typically includes a variety of computer-readable media. Computer-readable media can be any available media that can be accessed by computer 400 and includes both volatile and nonvolatile media, removable and non-removable media. By way of example, and not limitation, computer-readable media may comprise computer storage media and communication media. “Computer storage media” includes volatile and nonvolatile, removable and non-removable media implemented in any method or technology for storage of information such as computer-readable instructions, data structures, program modules, or other data. Computer storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by computer 400. Communication media typically embodies computer-readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network, fiber optic networks, or direct-wired connection and wireless media such as acoustic, RF, infrared and other wireless media. Combinations of any of the above should also be included within the scope of computer readable media.

The system memory 406 includes computer storage media in the form of volatile and/or nonvolatile memory such as read only memory (ROM) 410 and random access memory (RAM) 412. A basic input/output system 414 (BIOS), containing the basic routines that help to transfer information between elements within computer 400, such as during start-up, is typically stored in ROM 410. RAM 412 typically contains data and/or program modules that are immediately accessible to and/or presently being operated on by processing unit 404. By way of example, and not limitation, FIG. 4 illustrates operating system 416, application programs 418, other software components 420, and program data 422.

The computer 400 may also include other removable/non-removable, volatile/nonvolatile computer storage media. By way of example only, the computer system of FIG. 4 may include a hard disk drive 424 that reads from or writes to non-removable, nonvolatile magnetic media, a magnetic disk drive 426 that reads from or writes to a removable, nonvolatile magnetic disk 428, and an optical disk drive 430 that reads from or writes to a removable, nonvolatile optical disk 432 such as a CD ROM or other optical media. Other removable/non-removable, volatile/nonvolatile computer storage media that can be used in the exemplary operating environment include, but are not limited to, magnetic tape cassettes, flash memory cards, digital versatile disks, digital video tape, solid state RAM, solid state ROM, and the like. The hard disk drive 424 is typically connected to the system bus 408 through a non-removable memory interface such as data media interface 434, and magnetic disk drive 426 and optical disk drive 430 are typically connected to the system bus 408 by a removable memory interface.

The drives and their associated computer storage media discussed above and illustrated in FIG. 4 provide storage of computer-readable instructions, data structures, program modules, and other data for computer 400. In FIG. 4, for example, hard disk drive 424 is illustrated as storing operating system 416′, application programs 418′, software components 420′, and program data 422′. Note that these components can either be the same as or different from operating system 416, application programs 418, software components 420, and program data 422. Operating system 416, application programs 418, other program modules 420, and program data 422 are given different numbers here to illustrate that, at a minimum, they are different copies. A user may enter commands and information into the computer 400 through input devices such as a keyboard 436 and pointing device 438, commonly referred to as a mouse, trackball, or touch pad. Other input devices (not shown) may include a microphone 440, joystick, game pad, satellite dish, scanner, a remote control unit, or the like. These and other input devices are often connected to the processing unit 404 through an input/output (I/O) interface 442 that is coupled to the system bus, but may be connected by other interface and bus structures, such as a parallel port, game port, or a universal serial bus (USB). Additionally, in some embodiments, the pointing device 438 may be communicatively coupled to the keyboard 436. In some embodiments the pointing device 438 may function while either docked or undocked with the keyboard 436. A monitor 444 or other type of display device is also connected to the system bus 406 via an interface, such as a video adapter 446. In addition to the monitor 444, computers may also include other peripheral output devices (e.g., speakers) and one or more printers 470, which may be connected through the I/O interface 442.

The computer may operate in a networked environment using logical connections to one or more remote computers, such as a remote computing device 450. The remote computing device 450 may be a personal computer, a server, a router, a network PC, a peer device or other common network node, and typically includes many or all of the elements described above relative to computer 400. The logical connections depicted in FIG. 4 include a local area network (LAN) 452 and a wide area network (WAN) 454. Although the WAN 454 shown in FIG. 4 is the Internet, the WAN 454 may also include other networks. Such networking environments are commonplace in offices, enterprise-wide computer networks, intranets, and the like.

When used in a LAN networking environment, the computer 400 is connected to the LAN 452 through a network interface or adapter 456. When used in a WAN networking environment, the computer 400 typically includes a modem 458 or other means for establishing communications over the Internet 454. The modem 458, which may be internal or external, may be connected to the system bus 406 via the I/O interface 442, or other appropriate mechanism. In a networked environment, program modules depicted relative to the computer 400, or portions thereof, may be stored in the remote computing device 450. By way of example, and not limitation, FIG. 4 illustrates remote application programs 460 as residing on remote computing device 450. It will be appreciated that the network connections shown are exemplary and other means of establishing a communications link between the computers may be used.

Moreover, some embodiments may be provided as computer program products, which may include a machine-readable or computer-readable medium having stored thereon instructions used to program a computer (or other electronic devices) to perform a process discussed herein. The machine-readable medium may include, but is not limited to, floppy diskettes, hard disk, optical disks, CD-ROMs, and magneto-optical disks, ROMs, RAMs, erasable programmable ROMs (EPROMs), electrically EPROMs (EEPROMs), magnetic or optical cards, flash memory, or other suitable types of media or computer-readable media suitable for storing electronic instructions and/or data. Moreover, data discussed herein may be stored in a single database, multiple databases, or otherwise in select forms (such as in a table).

Reference in the specification to “one embodiment” or “an embodiment” means that a particular feature, structure, or characteristic described in connection with the embodiment is included in at least an implementation. The appearances of the phrase “in one embodiment” in various places in the specification are not necessarily all referring to the same embodiment.

What is claimed is:

1. A keyboard assembly, comprising:
a keyboard coupled to a power source; and
a rechargeable mouse coupled to the keyboard.

2. The keyboard assembly of claim 1, wherein the power supply is coupled to a computer.

3. The keyboard assembly of claim 2, wherein the keyboard is coupled via a cable that comprises a power channel and a data channel.

4. The keyboard assembly of claim 1, further comprising means for data communication.

5. The keyboard assembly of claim 1, further comprising a dock to receive a mouse.

6. The keyboard assembly of claim 5, wherein the dock comprises a charging module.

7. The keyboard assembly of claim 1, further comprising a means for communicating between the mouse and the keyboard.

8. A computer system, comprising:
at least one processor;
at least one memory form;
at least one user interface;
a keyboard coupled to a power supply;
a rechargeable mouse coupled to the keyboard; and
a basic input/output system comprising logic to:
detect the presence of said keyboard; and
activate an interface control module in response to the presence of said keyboard.

9. The computer system of claim 8, wherein the power supply is coupled to a computer.

10. The computer system of claim 9, wherein the keyboard is coupled via a cable that comprises a power channel and a data channel.

11. The computer system of claim 8, further comprising means for data communication.

12. The computer system of claim 8, further comprising a dock to receive a mouse.

13. The computer system of claim 12, wherein the dock comprises a charging module.

14. The computer system of claim 8, further comprising a means for communicating between the mouse and the keyboard.

15. A method, comprising:
initiating power on self test processing in the basic input/output system of a computing device;
detecting the presence of a keyboard system input; and
activating a keyboard control module in response to the presence of a keyboard.

16. The method of claim 15, wherein the keyboard control module:
detects a mouse; and
activates a Charging Module when the mouse is not charged above a threshold level.

17. The method of claim 16, wherein the Charging Module:
detects the mouse in the docking station; and
activates the charging process to recharge the mouse.

18. The method of claim 16, wherein the Charging Module:
detects the mouse is not in the docking station;
signals the computing device to prompt the user to place the mouse in the charging device; and
activates the charging process to recharge the mouse.

19. The method of claim 15, wherein the keyboard control module:
detects that the mouse is not docked in the keyboard docking station; and
activates the primary mouse functionality.

20. The method of claim 15, wherein the keyboard control module:
detects that the mouse is docked in the keyboard docking station; and
activates an alternative mouse functionality.
